(19) United States
(12) Patent Application Publication
(10) Pub. No.: US 2023/0341785 A1
(43) Pub. Date: Oct. 26, 2023

(54) LITHOGRAPHIC APPARATUS, METROLOGY SYSTEMS, AND METHODS THEREOF

(71) Applicants: ASML Netherlands B.V., Veldhoven (NL); ASML Holding N.V., Veldhoven (NL)

(72) Inventors: Simon Reinald HUISMAN, Eindhoven (NL); Sergey MALYK, Brookfield, CT (US); Yuxiang LIN, Wilton, CT (US); Daan Maurits SLOTBOOM, Wolphaartsdijk (NL)

(73) Assignees: ASML Netherlands B.V., Veldhoven (NL); ASML Holding N.V., Veldhoven (NL)

(21) Appl. No.: 18/002,258

(22) PCT Filed: Jun. 7, 2021
(86) PCT No.: PCT/EP21/65197

§ 371 Date: Dec. 16, 2022

(51) Int. Cl. G03F 7/20; G03F 9/00

(52) U.S. Cl. CPC G03F 7/70625; G03F 9/7088; G03F 7/705

(57) ABSTRACT

A system includes an illumination system, an optical element, a switching element and a detector. The illumination system includes a broadband light source that generates a beam of radiation. The dispersive optical element receives the beam of radiation and generates a plurality of light beams having a narrower bandwidth than the broadband light source. The optical switch receives the plurality of light beams and transmits each one of the plurality of light beams to a respective one of a plurality of alignment sensor of a sensor array. The detector receives radiation returning from the sensor array and to generate a measurement signal based on the received radiation.

### CROSS-REFERENCE TO RELATED APPLICATIONS

This application claims priority of U.S. Provisional Patent Application No. 63/040,971, which was filed on Jun. 18, 2020, and which is incorporated herein in its entirety by reference.

### FIELD

The present disclosure relates to a lithographic apparatus, for example, a lithographic apparatus for determining a characteristic of a pattern.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

Another lithographic system is an interferometric lithographic system where there is no patterning device, but rather a light beam is split into two beams, and the two beams are caused to interfere at a target portion of the substrate through the use of a reflection system. The interference causes lines to be formed at the target portion of the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay (OV) error between two layers formed in or on the patterned substrate. Properties of the substrate can be determined by comparing the properties of an illumination beam before and after the beam has been reflected or scattered by the substrate.

### SUMMARY

Knowledge on material layer thicknesses in lithography steps is important to maximize performance and yield. Accordingly, there is a need to determine layer thicknesses efficiently.

In some embodiments, a system includes an illumination system, a detection system, and processing circuitry. The illumination system generates radiation at a plurality of wavelengths and to irradiate a metrology mark on a substrate. The detection system detects light intensities at the plurality of wavelengths based on light scattered from the metrology mark. The processing circuitry analyzes the detected light intensities and determines at least one characteristic of a structure on the substrate based on the analyzing. The metrology mark is configured to enhance an optical response at the plurality of wavelengths.

In some embodiments, a method includes irradiating a metrology mark on a substrate with radiation at a plurality of wavelengths, receiving scattered radiation at a detector. The scattered radiation includes radiation scattered from the metrology mark. The method also includes generating a detection signal representative of an intensity of the received scattered radiation, analyzing the detection signal to determine a position of the metrology mark; and determining at least one characteristic of a structure on the substrate based on the analyzing. The metrology mark has an enhanced optical response at the plurality of wavelengths.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of alignment apparatuses, according to some embodiments.

FIG. 5 illustrates an alignment mark, according to some embodiments.

FIGS. 6A and 6B illustrates exemplary read outs from the alignment sensor, according to some embodiments.

FIG. 7 illustrates a cross section of an alignment mark, according to some embodiments.

FIGS. 8A and 8B illustrate the aligned position with respect to an arbitrary reference for X and Y polarization and for different resist thickness, according to some embodiments.

FIG. 9 is an exemplary flow chart that illustrates a lithography process, according to some embodiments.

FIGS. 10A and 10B illustrate exemplary conjugate pair of alignment marks, according to some embodiments.

FIGS. 11A and 11B illustrate exemplary alignment position deviation vectors, according to some embodiments.

FIG. 12 illustrates an exemplary alignment mark, according to some embodiments.

FIG. 13 illustrates an exemplary alignment mark, according to some embodiments.

FIG. 14 shows method steps for performing functions of embodiments described herein, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

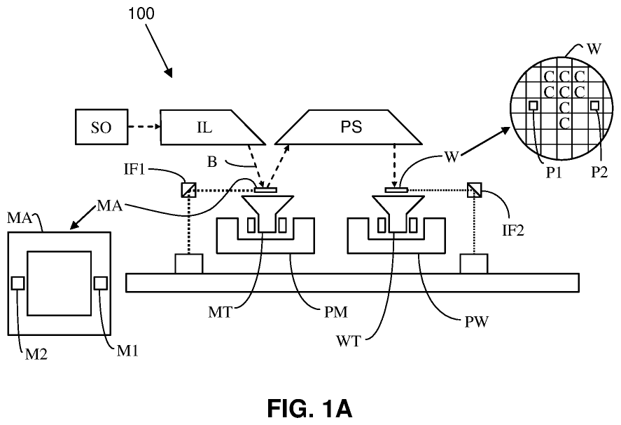

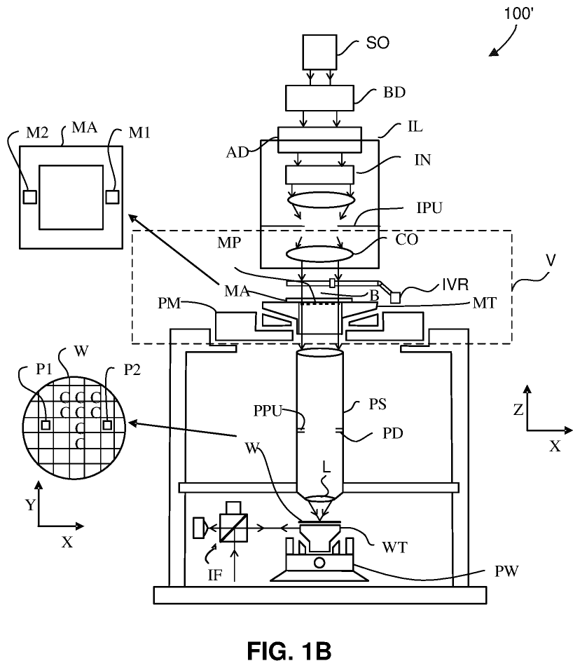

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, is submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MP′ of the mask pattern MP, where image MP′ is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IF (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

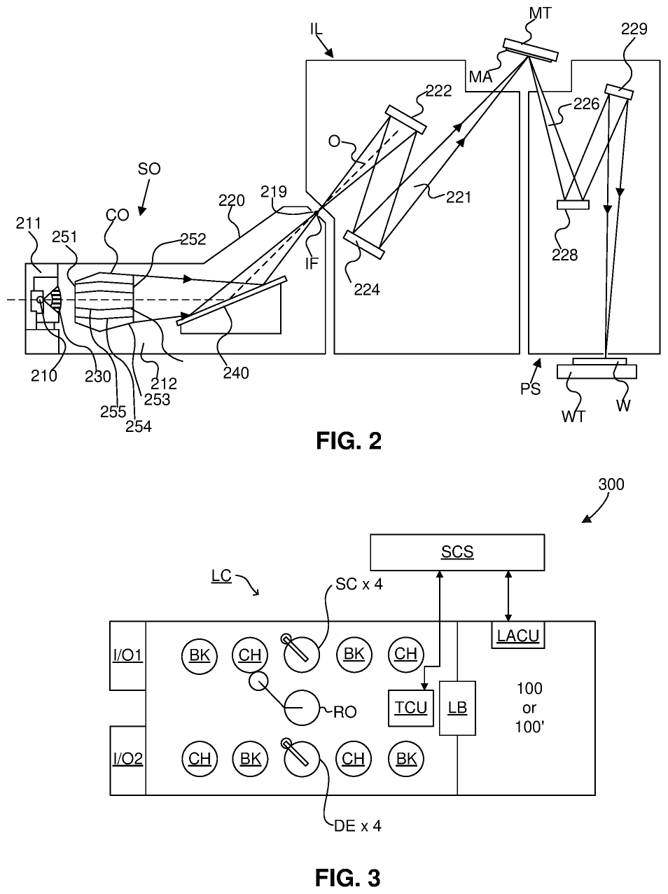

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

Exemplary Lithographic Cell

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, 1/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

Exemplary Inspection Apparatuses

In order to control the lithographic process to place device features accurately on the substrate, alignment marks are generally provided on the substrate, and the lithographic apparatus includes one or more alignment apparatuses and/or systems by which positions of marks on a substrate must be measured accurately. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.), which is incorporated by reference herein in its entirety. Generally, marks are measured separately to obtain X- and Y-positions. A combined X- and Y-measurement may be performed using the techniques described in U.S. Publication No. 2009/195768 A (Bijnen et al.), which is also incorporated by reference herein in its entirety.

The terms “inspection apparatus,” “metrology apparatus,” and the like may be used herein to refer to, e.g., a device or system used for measuring a property of a structure (e.g., overlay error, critical dimension parameters) or used in a lithographic apparatus to inspect an alignment of a wafer (e.g., alignment apparatus).

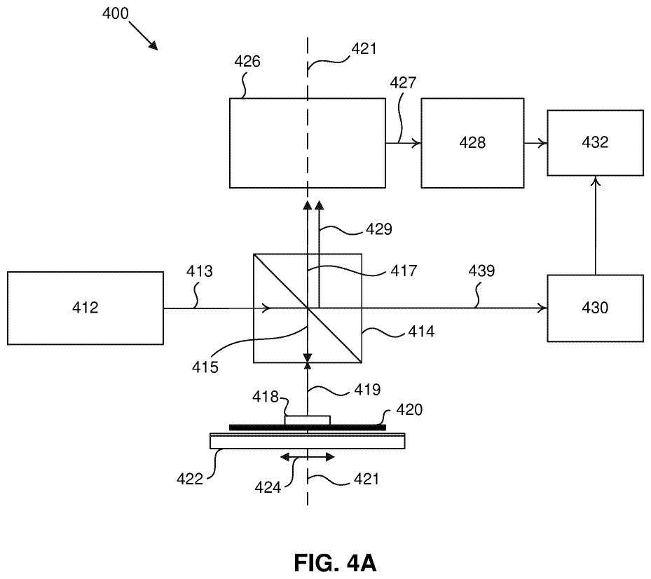

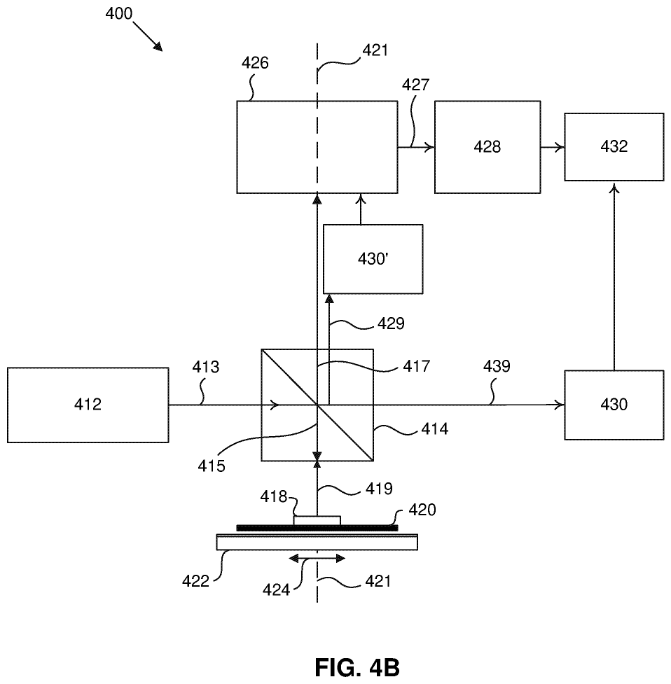

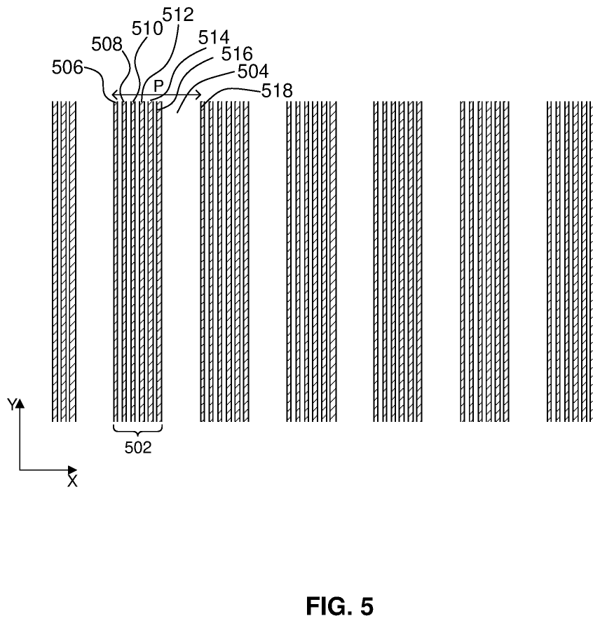

FIG. 4A shows a schematic of a cross-sectional view of a metrology apparatus 400, according to some embodiments. In some embodiments, metrology apparatus 400 may be implemented as part of lithographic apparatus 100 or 100′. Metrology apparatus 400 may be configured to align a substrate (e.g., substrate W) with respect to a patterning device (e.g., patterning device MA). Metrology apparatus 400 may be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

In some embodiments, metrology apparatus 400 may include an illumination system 412, a beam splitter 414, an interferometer 426, a detector 428, a beam analyzer 430, and an overlay calculation processor 432. Illumination system 412 may be configured to provide an electromagnetic narrow band radiation beam 413 having one or more passbands. In an example, the one or more passbands may be within a spectrum of wavelengths between about 500 nm to about 900 nm. In another example, the one or more passbands may be discrete narrow passbands within a spectrum of wavelengths between about 500 nm to about 900 nm. Illumination system 412 may be further configured to provide one or more passbands having substantially constant center wavelength (CWL) values over a long period of time (e.g., over a lifetime of illumination system 412). Such configuration of illumination system 412 may help to prevent the shift of the actual CWL values from the desired CWL values, as discussed above, in current alignment systems. And, as a result, the use of constant CWL values may improve long-term stability and accuracy of alignment systems (e.g., metrology apparatus 400) compared to the current alignment apparatuses.

In some embodiments, beam splitter 414 may be configured to receive radiation beam 413 and split radiation beam 413 into at least two radiation sub-beams. For example, radiation beam 413 may be split into radiation sub-beams 415 and 417, as shown in FIG. 4A. Beam splitter 414 may be further configured to direct radiation sub-beam 415 onto a substrate 420 placed on a stage 422. In one example, the stage 422 is movable along direction 424. Radiation sub-beam 415 may be configured to illuminate an alignment mark or a target 418 located on substrate 420. Alignment mark or target 418 may be coated with a radiation sensitive film. In some embodiments, alignment mark or target 418 may have one hundred and eighty degrees (i.e., 180°) symmetry. That is, when alignment mark or target 418 is rotated 180° about an axis of symmetry perpendicular to a plane of alignment mark or target 418, rotated alignment mark or target 418 may be substantially identical to an unrotated alignment mark or target 418. The target 418 on substrate 420 may be a resist layer grating comprising bars that are formed of solid resist lines, a product layer grating, a composite grating stack in an overlay target structure comprising a resist grating overlaid or interleaved on a product layer grating, or the like. The bars may alternatively be etched into the substrate. This pattern may be sensitive to chromatic aberrations in the lithographic projection apparatus, particularly the projection system PL, and illumination symmetry and the presence of such aberrations may manifest themselves in a variation in the printed grating. In one example, an in-line method used in device manufacturing for measurements of line width, pitch, and critical dimension makes use of a technique known as “scatterometry”. For example, methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In some embodiments, beam splitter 414 may be further configured to receive diffraction radiation beam 419 and split diffraction radiation beam 419 into at least two radiation sub-beams, according to an embodiment. Diffraction radiation beam 419 may be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements may be used to obtain the similar result of illuminating alignment mark or target 418 on substrate 420 and detecting an image of alignment mark or target 418.

As illustrated in FIG. 4A, interferometer 426 may be configured to receive radiation sub-beam 417 and diffracted radiation sub-beam 429 through beam splitter 414. In an example embodiment, diffracted radiation sub-beam 429 may be at least a portion of radiation sub-beam 415 that may be reflected from alignment mark or target 418. In an example of this embodiment, interferometer 426 comprises any appropriate set of optical-elements, for example, a combination of prisms that may be configured to form two images of alignment mark or target 418 based on the received diffracted radiation sub-beam 429. It should be appreciated that a good quality image need not be formed, but that the features of alignment mark 418 should be resolved. Interferometer 426 may be further configured to rotate one of the two images with respect to the other of the two images 180° and recombine the rotated and unrotated images interferometrically.

In some embodiments, detector 428 may be configured to receive the recombined image via interferometer signal 427 and detect interference as a result of the recombined image when alignment axis 421 of metrology apparatus 400 passes through a center of symmetry (not shown) of alignment mark or target 418. Such interference may be due to alignment mark or target 418 being 180° symmetrical, and the recombined image interfering constructively or destructively, according to an example embodiment. Based on the detected interference, detector 428 may be further configured to determine a position of the center of symmetry of alignment mark or target 418 and consequently, detect a position of substrate 420. According to an example, alignment axis 421 may be aligned with an optical beam perpendicular to substrate 420 and passing through a center of image rotation interferometer 426. Detector 428 may be further configured to estimate the positions of alignment mark or target 418 by implementing sensor characteristics and interacting with wafer mark process variations.

In a further embodiment, detector 428 may determine the position of the center of symmetry of alignment mark or target 418 by performing one or more of the following measurements:
1. measuring position variations for various wavelengths (position shift between colors);
2. measuring position variations for various orders (position shift between diffraction orders); and/or
3. measuring position variations for various polarizations (position shift between polarizations).
   This data may for example be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, an ORION sensor, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 may be configured to receive and determine an optical state of diffracted radiation sub-beam 439. The optical state may be a measure of beam wavelength, polarization, or beam profile. Beam analyzer 430 may be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 may be configured to determine a position of metrology apparatus 400 or any other reference element such that the center of symmetry of alignment mark or target 418 can be known with reference to metrology apparatus 400 or any other reference element. Beam analyzer 430 may be a point or an imaging polarimeter with some form of wavelength-band selectivity. In some embodiments, beam analyzer 430 may be directly integrated into metrology apparatus 400, or connected via fiber optics of several types: polarization preserving single mode, multimode, or imaging, according to other embodiments.

In some embodiments, beam analyzer 430 may be further configured to determine the overlay data between two patterns on substrate 420. One of these patterns may be a reference pattern on a reference layer. The other pattern may be an exposed pattern on an exposed layer. The reference layer may be an etched layer already present on substrate 420. The reference layer may be generated by a reference pattern exposed on the substrate by lithographic apparatus 100 and/or 100′. The exposed layer may be a resist layer exposed adjacent to the reference layer. The exposed layer may be generated by an exposure pattern exposed on substrate 420 by lithographic apparatus 100 or 100′. The exposed pattern on substrate 420 may correspond to a movement of substrate 420 by stage 422. In some embodiments, the measured overlay data may also indicate an offset between the reference pattern and the exposure pattern. The measured overlay data may be used as calibration data to calibrate the exposure pattern exposed by lithographic apparatus 100 or 100′, such that after the calibration, the offset between the exposed layer and the reference layer may be minimized.

In some embodiments, beam analyzer 430 may be further configured to determine a model of the product stack profile of substrate 420, and may be configured to measure overlay, critical dimension, and focus of target 418 in a single measurement. The product stack profile contains information on the stacked product such as alignment mark, target 418, substrate 420, or the like and may include mark process variation-induced optical signature metrology that is a function of illumination variation. The product stack profile may also include product grating profile, mark stack profile, mark asymmetry information, or the like. An example of beam analyzer 430 may be found in the metrology apparatus known as Yieldstar™ manufactured by ASML, Veldhoven, The Netherlands, as described in U.S. Pat. No. 8,706,442, which is incorporated by reference herein in its entirety. Beam analyzer 430 may be further configured to process information related to a particular property of an exposed pattern in that layer. For example, beam analyzer 430 may process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (e.g., sensor array 1006) may be connected to beam analyzer 430, and allow the possibility of accurate stack profile detection as discussed below. For example, detector 428 may be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but may require separate pre-amps. The number of elements is therefore limited. CCD linear arrays offer many elements that may be read-out at high speed and are especially of interest if phase-stepping detection is used.

In some embodiments, a second beam analyzer 430′ may be configured to receive and determine an optical state of diffracted radiation sub-beam 429, as shown in FIG. 4B. The optical state may be a measure of beam wavelength, polarization, beam profile, or the like. Second beam analyzer 430′ may be identical to beam analyzer 430. Alternatively, second beam analyzer 430′ may be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ may also be configured to determine a position of metrology apparatus 400, or any other reference element, such that the center of symmetry of alignment mark or target 418 may be known with reference to metrology apparatus 400, or any other reference element. Second beam analyzer 430′ may be further configured to determine the overlay data between two patterns and a model of the product stack profile of substrate 420. Second beam analyzer 430′ may also be configured to measure overlay, critical dimension, and focus of target 418 in a single measurement.

In some embodiments, second beam analyzer 430′ may be directly integrated into metrology apparatus 400, or it may be connected via fiber optics of several types: polarization preserving single mode, multimode, or imaging, according to other embodiments. Alternatively, second beam analyzer 430′ and beam analyzer 430 may be combined to form a single analyzer (not shown) configured to receive and determine the optical states of both diffracted radiation sub-beams 429 and 439.

In some embodiments, processor 432 receives information from detector 428 and beam analyzer 430. For example, processor 432 may be an overlay calculation processor. The information may comprise a model of the product stack profile constructed by beam analyzer 430. Alternatively, processor 432 may construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 may create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 may utilize the basic correction algorithm to characterize the metrology apparatus 400 with reference to wafer marks and/or alignment marks 418.

In some embodiments, processor 432 may be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 may utilize a clustering algorithm to group the marks into sets of similar constant offset error, and create an alignment error offset correction table based on the information. The clustering algorithm may be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error may be deduced. Table 1 illustrates how this may be performed. The smallest measured overlay in the example shown is −1 nm. However, this is in relation to a target with a programmed overlay of −30 nm. Consequently, the process has introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value may be taken to be the reference point and, relative to this, the offset may be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 may also be obtained from marks and target 418 under different illumination settings, the illumination setting, which results in the smallest overlay error, and its corresponding calibration factor, may be determined and selected. Following this, processor 432 may group marks into sets of similar overlay error. The criteria for grouping marks may be adjusted based on different process controls, for example, different error tolerances for different processes.

In some embodiments, processor 432 may confirm that all or most members of the group have similar offset errors, and apply an individual offset correction from the clustering algorithm to each mark, based on its additional optical stack metrology. Processor 432 may determine corrections for each mark and feed the corrections back to lithographic apparatus 100 or 100′ for correcting errors in the overlay, for example, by feeding corrections into the alignment apparatus 400.

In some aspects, knowledge of material layer thicknesses in lithography steps may be desirable to maximize performance and yield. For example, the more knowledge about the thicknesses of the layers, both of the product and the resist, the more one can correct for deviations during processing (e.g., during exposure). External systems and/or metrology apparatuses associated with the lithography apparatus may be used to characterize layer/device thicknesses (e.g., non-destructive tools like ellipsometry such as Yieldstar™, destructive tools like scanning electron microscope (SEM) and atomic force microscopy (AFM)). However, using external systems can increase the processing time. Described herein are various embodiments including methods and systems to determine layer thicknesses using data from an alignment sensor. In some aspects, the methods and systems described herein improve processing times as all wafers, substrates, devices, are measured using an alignment sensor during processing. Thus, in some aspects the method described herein may provide a thickness profile of a device without increasing the processing time or the need of additional external systems.

The present disclosure provides various embodiments of an alignment mark or metrology mark on a substrate (e.g., wafer W). The alignment mark may be used in an alignment system discussed above. Each of these embodiments of the alignment system may be used to determine position of the alignment mark, and consequently, positions variations at a plurality of wavelengths. One or more characteristics of the device (e.g., layer thicknesses above and below the alignment mark) can be determined based on the position variations at the plurality of wavelengths.

In one embodiment, the metrology mark has an enhanced color response. In other words, the optical response of the metrology mark varies for different wavelengths, for example, the extracted aligned position as a function of the wavelength. In one example, the metrology mark is sub-segmented. For example, the metrology mark may be a sub-segmented grating formed in one or more layers.

FIG. 5 illustrates an alignment mark 500 according to one example. Alignment mark 500 may have periodic patterns including lines 502, spaces 504, and a pitch P, as shown in FIG. 5.

In some aspects, each of lines 502 has a plurality of sub-segments 506 through 516. The alignment mark may include different numbers of sub-segments. For example, FIG. 5 shows six sub-segments, however as would be understood by one of ordinary skill in the art, lines 502 may include less or more than 6 sub-segments. The term “pitch” as used herein refers to a distance from a given point on one of the line to the same point on an adjacent line, as shown (e.g., from sub-segment 506 to sub-segment 518).

In some aspects, reach sub-segment has a different width. For example, a width of each of the sub-segments 506 through 516 has a width different from one another. The width of sub-segment 506 may be smaller than the width of sub-segment 516. In one example, the width of the sub-segment increases in a first direction “X”. The above discussed spaces in the patterns of the alignment mark may be void. The alignment mark may be formed on the stack (device) and/or on the resist.

Color to color responses are caused by mark asymmetry as unwanted consequence of processing steps. Marks asymmetry is unavoidable and leads to a small color to color response. The alignment mark 500 described herein has an enhanced color response (color to color variation) due to the artificial asymmetry introduced by controlling the sub-segmentation and/or creating deformed marks. The artificial asymmetry can be made much stronger than the unwanted mark asymmetry, making the artificial symmetry an effective gauge for layer thickness variations.

In one example, the alignment mark 500 is etched under an angle to create deformed marks. The deformed marks are used to determine the thickness of the layers of the device as described herein.

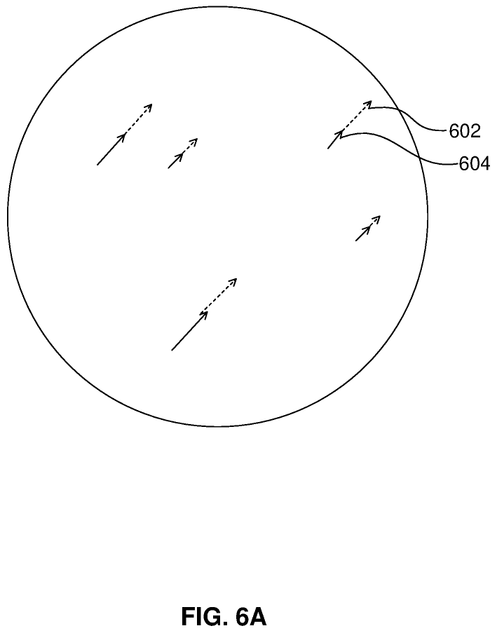

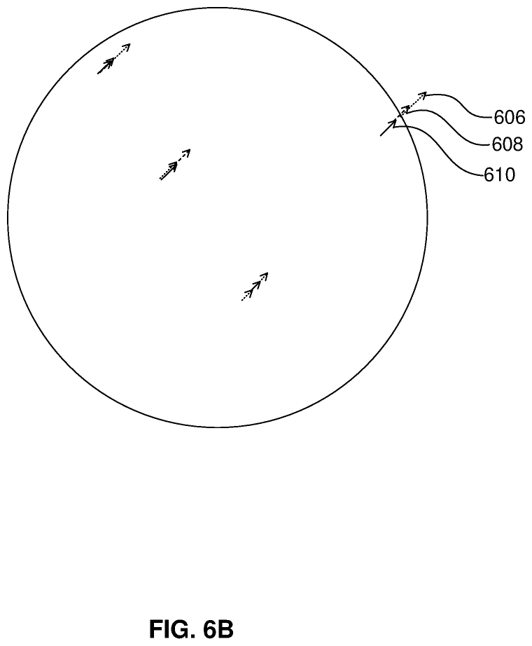

FIGS. 6A and 6B illustrate an exemplary read out from the alignment sensor at different wavelengths and polarizations according to one example. The read out shows alignment position deviation (APD) vectors for alignment mark 500 illustrated in FIG. 5. In this example, the alignment mark 500 was exposed on resist in a bare silicon wafer. In some aspects, position deviations shown in FIGS. 6A and 6B are used to determine the thickness of the resist layer. The APD vectors for different wavelengths show the position variations. For example, vector 602 corresponds to data (reading) for a first wavelength (e.g., 532 nm) and vector 604 corresponds to a reading at a second wavelength (e.g., 632 nm). Vectors 606, 608, 610 show the position deviations at different wavelengths and different polarizations. Position deviations at the plurality of wavelengths may be read consecutively or simultaneously. In other words, the alignment mark may be illuminated with radiation sequentially or simultaneously for the plurality of wavelengths. The variation in the length in the vectors indicate the strong color response of alignment mark 500. Thus, alignment sensor is sensitive to the plurality of wavelengths due to the sub segmentation of alignment mark 500.

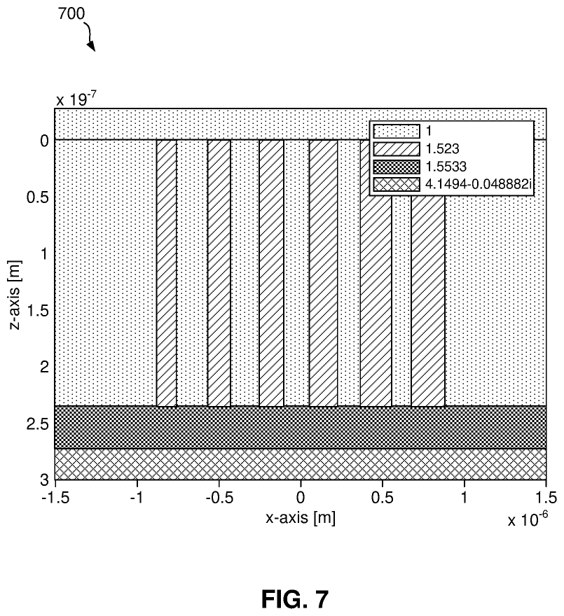

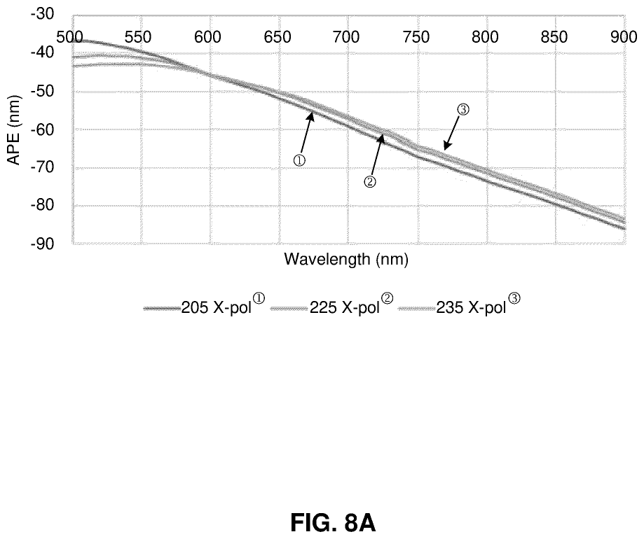

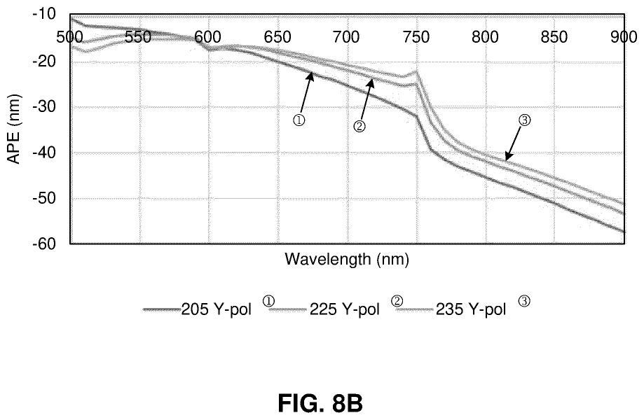

FIG. 7 illustrates a cross section of a model 700 of the alignment mark 500. In some aspects, the alignment mark is etched on resist on a silicon substrate. FIG. 7 shows the refractive index at a wavelength of 532 nm for each of the layers according to some embodiments. Model 700 is used to determine the difference in aligned position for the different wavelengths as shown in FIGS. 8A and 8B according to some embodiments.

FIGS. 8A and 8B illustrate the aligned position with respect to an arbitrary reference (APE) for X and Y polarization and for different resist thicknesses according to some embodiments. In some aspects, the APE represents a change or shift in alignment position from the alignment mark on the substrate with respect to the arbitrary reference. In one example, the APE is determined for three thicknesses (205 nm, 225 nm, and 235 nm) in a wavelength range from 500 nm to 900 nm. As shown from FIGS. 8A and 8B, the extracted aligned position on an alignment mark may have a color dependent response, that depends on the layer thickness. Comparing the color dependent responses allows to reconstruct the actual layer thickness. In one example, the actual layer thickness may be determined by comparing difference between the simulated aligned positions at multiple wavelengths to a difference between measured aligned positions at the multiple wavelengths. For example, for a 205 nm thick mark measured at 600 nm and at 700 nm, the position error at 700 nm is larger than the position error at 600 nm. For a 235 nm thick mark, the position error is different than the position error for the 205 nm thick mark. Thus, the color response may depend on the actual thickness of the mark.

In one example, a rigorous coupled wave analysis (RCWA) may be used to predict the color response of the alignment mark in aligned position and for different layer thickness variations. Other numerical modeling techniques may also be used as would be understood by one of ordinary skill in the art. Modeled color responses may be stored in a library or database. The detected response may be compared to previously measured or simulated signal of alignment marks to find a best fit using the model.

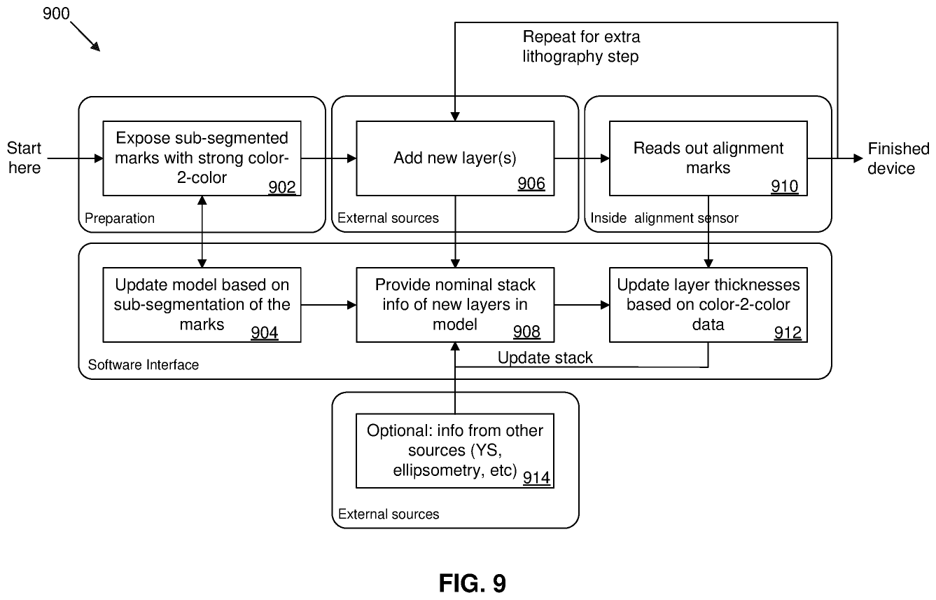

FIG. 9 is an exemplary flow chart that illustrates a lithography process 900 according to one example. The method steps of FIG. 9 can be performed in any conceivable order and it is not required that all steps be performed. Moreover, the method steps of FIG. 9 described above merely reflect an example of steps and are not limiting. That is, further method steps and functions may be envisaged based embodiments described in reference to the figures above

In step 902, sub-segmented alignment marks with a strong color to color response are exposed. The sub-segmented alignment marks may be selected based on a particular application or device. In step 904, a model is updated based on sub-segmentation of the marks. In step 906, additional layers are added to the sub-segmented mark. In step 908, nominal information associated with the additional layers are provided to the model. In step 910, alignment marks are read out using an alignment sensor for the additional layer. The layer thickness is determined based on the color response. In step 912, layer thicknesses are updated based on the data from the alignment sensor and the model is updated. Steps 906 and 910 can be repeated at additional lithography steps. In step 914, additional data from an external system may be used to update the model.

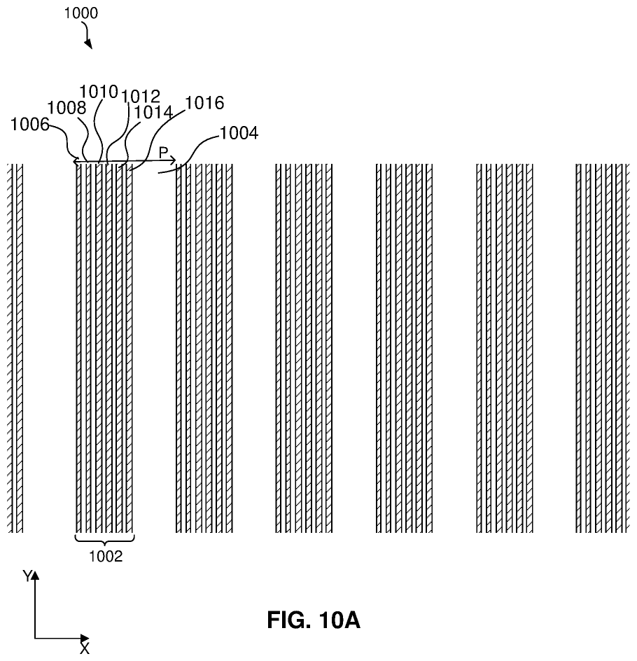

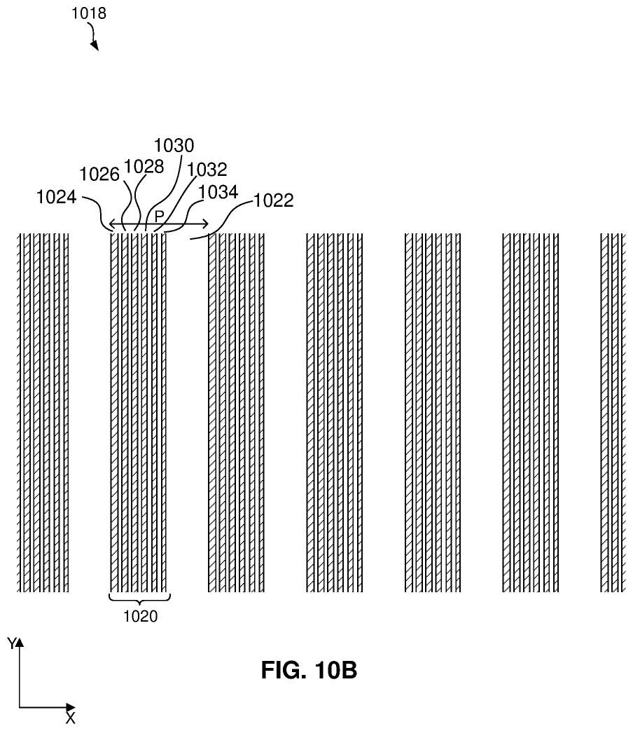

In one example, conjugate alignment marks may be used to determine the one or more characteristics. Conjugate alignment marks are mirrored pairs to correct for mark-asymmetry caused by processing steps (e.g., etch process). In other words, the color to color response will be a function of the sub-segmentation (i.e., artificial asymmetry) and not a function of both the sub-segmentation and the mark-asymmetry caused by processing steps. FIGS. 10A and 10B illustrates two conjugates alignment marks according to some embodiments.

A first alignment mark 1000 and a second alignment mark 1018 may be used to determine the one or more characteristics of the device. Second alignment mark 1018 may correspond to the conjugate of first alignment mark 1000. Alignment mark 1000 may have a patterns including lines 1002, spaces 1004, and a pitch P, as shown in FIG. 10A. Each of lines 1002 may have a plurality of sub-segments 1006 through 1016. The alignment mark may include different numbers of sub-segments. Second alignment mark 1018 may have patterns including lines 1020, spaces 1022, and a pitch P (same pitch of first alignment mark 1000), as shown in FIG. 10B. In some aspects, each of lines 1020 has a plurality of sub-segments 1024 through 1034. In some aspects, each line 1020 of second alignment mark 1018 includes the same number of sub-segments as line 1002 of first alignment mark 1000. In some aspects, the width of each sub-segment increases in the positive X-direction in first alignment mark 1000 whereas the width of each sub-segment decreases in the positive X-direction in second alignment mark 1018. First alignment mark 1000 and second alignment mark 1018 are positioned closely together. As would be understood by one of ordinary skill in the art, the closer the marks (e.g., first alignment mark 1000 and second alignment mark 1018) are placed together, the more likely that both marks suffer from the same type of asymmetry (e.g., caused by processing steps). If the marks are ‘far’ away, it may be that first alignment mark 1000 has a different type of asymmetry than second alignment mark 1018. Thus, making this method less effective, unless extra corrections have been applied in the modelling to quantify and deal with the difference in asymmetry.

Position variations may be determined for the first alignment mark and for second alignment mark simultaneously or consecutively. Estimated thicknesses may be then determined based on the position variations obtained from first alignment mark 1000 and second alignment mark 1018.

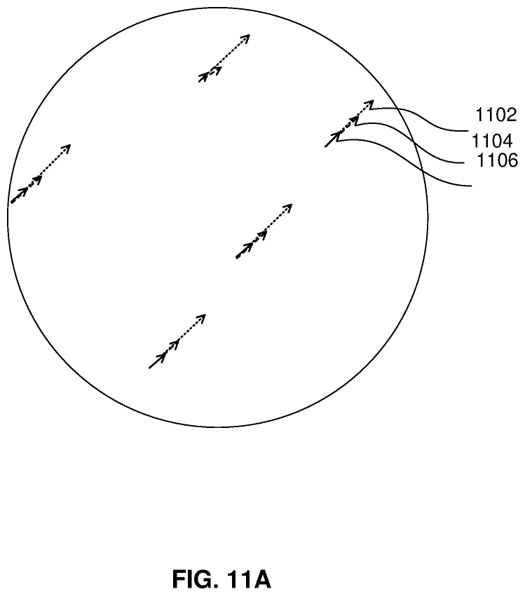

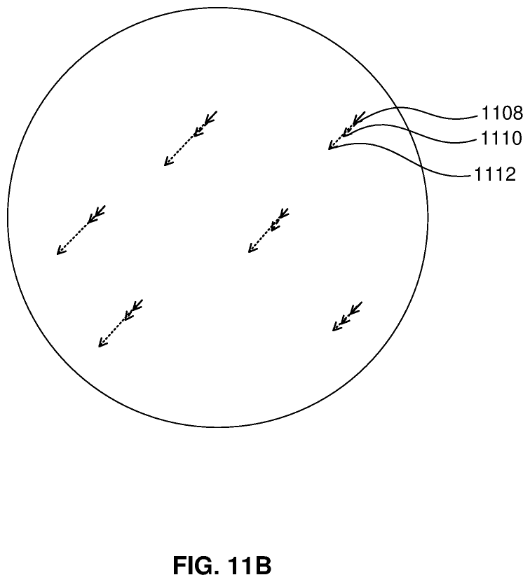

FIG. 11A illustrates the alignment position deviation for first alignment mark 1000 according to some embodiments. FIG. 11B illustrates the alignment position deviation for second alignment mark 1018 according to some embodiments. Vectors (e.g., vector 1102 at first wavelength, vector 1104 at second wavelength, vector 1106 at third wavelength) associated with the first alignment mark 1000 and vectors (e.g., vector 1108 at the first wavelength, vector 1110 at the second wavelength, at the third wavelength vector 1112) associated with the second alignment mark 1018 have opposite directions. Thus, any alignment deviations due to mark-asymmetry from processing may be accounted for and the estimated thickness refined based on the data from both of the alignment marks.

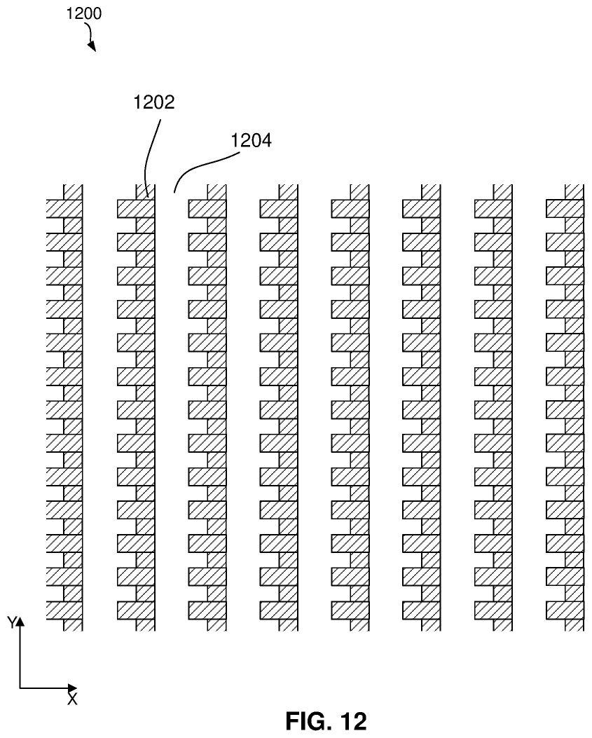

FIG. 12 illustrates an alignment mark 1200 having an enhanced color response according to one example. Alignment mark 1200 may have patterns including lines 1202 and spaces 1204, as shown in FIG. 12. Line 1202 may have a periodic pattern in the Y-direction. Line 1202 may include a periodic rectangular pattern having different duty cycles.

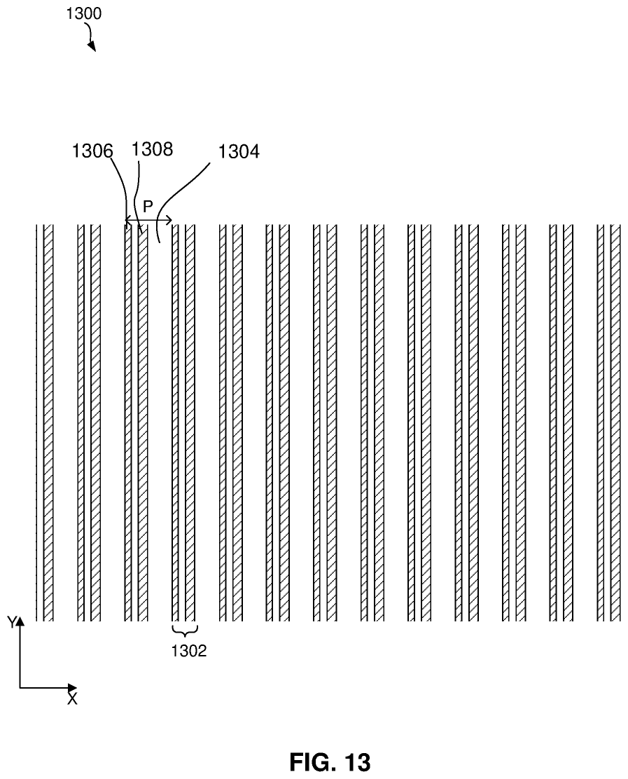

FIG. 13 illustrates an alignment mark 1300 according to one example. Alignment mark 1300 may have patterns including lines 1302, spaces 1304, and a pitch P, as shown in FIG. 13. In some aspects, each of lines 1302 has a first sub-segment 1306 and a second sub-segment 1308. In some aspects, first sub-segment 1306 and second sub-segment 1308 have different width.

In one embodiment, a combination of two or more alignment marks of different types may be used. The two or more alignment marks may be selected such as first alignment mark has a strong response at a first wavelength and second alignment mark has a strong response at a second wavelength. Position deviations may be determined at the first wavelength for the first alignment mark. Position deviations may be determined at the second wavelength for the second alignment mark. In other words, position deviations may be determined (read-out) at the wavelength at which the alignment mark exhibits the strongest response. For example, alignment mark 1200 and alignment mark 1300 may be exposed on the substrate. Position deviations at the first wavelength are obtained from alignment mark 1200 and position deviations at the third wavelength are obtained from alignment mark 1300. Position deviations from both alignment marks are used to determine the characteristic (e.g., thicknesses of the layers) using the model.

In one aspect, layer thicknesses can be extracted from image based overlay sensors that compare the position of one mark in one layer with respect to the position of another mark in another layer. Typically both gratings are present in the same picture. An overlay number is determined based on the extracted difference between position of a first grating and a second grating. An image-based overlay is very similar to alignment. A key difference is that for alignment the phase is compared against a fixed reference, to establish an absolute position measurement. For image-based overlay, conditions are more relaxed and the reference is formed by a second grating which is captured in the same snapshot/measurement region. The relative displacement between the two gratings can be used to determine overlay. This measurement can be performed without the need of benchmarking with a fixed reference. For an image-based overlay sensor that works with a camera, it is preferable if both gratings are captured simultaneously within a single image. However, this is not necessary and two images could, for example, be stitched together.

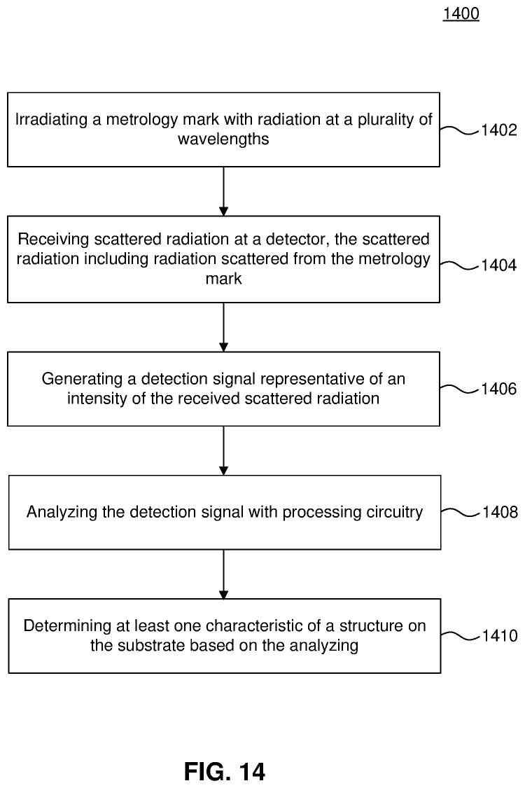

FIG. 14 shows method steps for performing functions described herein, according to some embodiments. The method steps of FIG. 14 can be performed in any conceivable order and it is not required that all steps be performed. Moreover, the method steps of FIG. 14 described above merely reflect an example of steps and are not limiting. That is, further method steps and functions may be envisaged based embodiments described in reference to FIGS. 1-13.

Method 1400 includes irradiating a metrology mark (alignment mark) on a substrate with radiation at a plurality of wavelengths, as illustrated in step 1402. The metrology mark has an enhanced optical response at the plurality of wavelengths. For example, metrology mark 500 of FIG. 5. Method 1400 also includes receiving scattered radiation at a detector, the scattered radiation including radiation scattered from the metrology mark, as illustrated in step 1404. Method 1400 further includes generating a detection signal representative of an intensity of the received scattered radiation as illustrated in step 1406. Method 1400 further includes analyzing the detection signal, as illustrated in step 1408. The analyzing includes determining a position of metrology mark at the plurality of wavelengths. Method 1400 further includes determining at least one characteristic of a structure on the substrate based on the analyzing, as illustrated in step 1410.

In one embodiment, the method further includes irradiating a first metrology mark of a first type having a first optical response, and irradiating a second metrology mark of a second type having a second optical response. The first metrology mark and the second metrology mark mirrors (or conjugate) of each other.

In other embodiments, the method further includes comparing data from multiple alignment marks having strong color response at different wavelengths to refine the model.

In one example, the analyzing is further based on the detected light intensities at the different polarizations. For example, measured position variations for various polarizations (position shift between polarizations) may be used in determining the at least one characteristic. The analyzing may include comparing a predicted response of the alignment mark at the plurality of wavelengths and at various polarizations with the measured position variations for the various polarizations at the plurality of wavelengths.

In one example, the analyzing further includes determining an intensity difference for the response at the plurality of wavelengths.

In one example, level sensor data may be correlated with the determined thicknesses using the methods described herein to improve the thickness estimate per mark location.

The embodiments may further be described using the following clauses:
1. An apparatus comprising:
   an illumination system configured to generate radiation at a plurality of wavelengths and to irradiate a metrology mark on a substrate;
   a detection system configured to detect light intensities at the plurality of wavelengths based on light scattered from the metrology mark; and
   processing circuitry configured to:
      analyze the detected light intensities to determine a position of the metrology mark, and
      determine at least one characteristic of a structure on the substrate based on the analyzing,
   wherein the metrology mark is configured to enhance an optical response at the plurality of wavelengths.
2. The apparatus of clause 1, wherein the at least one characteristic of the structure includes a thickness of one or more layers of the structure.
3. The apparatus of clause 1, wherein the metrology mark is sub-segmented.
4. The apparatus of clause 3, wherein the metrology mark includes a periodic structure including a substructure having a plurality of elements having width different from one another.
5. The apparatus of clause 4, wherein the substructure includes two elements having different widths.
6. The apparatus of clause 4, wherein the plurality of elements has decreasing/increasing line widths.
7. The apparatus of clause 3, wherein the metrology mark includes conjugate pairs.
8. The apparatus of clause 3, wherein the metrology mark includes a periodic structure in a first dimension, the periodic structure including a substructure having a plurality of elements having a periodicity in a second dimension, the first direction being perpendicular to the second direction.
9. The apparatus of clause 1, wherein the analyzing includes determining positioning variations of the metrology mark at the plurality of wavelengths based on the detected light intensities.
10. The apparatus of clause 1, wherein the processing circuitry is further configured to:
   determine a response of the metrology mark at the plurality of wavelengths based on a predetermined model; and
   compare the detected intensities to the modeled response to determine the at least one characteristic.
11. The apparatus of clause 10, wherein the processing circuitry is further configured to:
   acquire data corresponding to the at least one characteristic from an external system;
   compare the determined at least one characteristic of the structure with the acquired data; and
   update the predetermined model based on the comparison.
12. The apparatus of clause 1, wherein
   the illumination system is further configured to generate radiation at different polarizations;
   the detection system is further configured to detect light intensities at the different polarizations; and
   the analyzing is based on the detected light intensities at the plurality of wavelengths and at the different polarizations.
13. A method comprising:
   irradiating a metrology mark on a substrate with radiation at a plurality of wavelengths;
   receiving scattered radiation at a detector, the scattered radiation including radiation scattered from the metrology mark;
   generating a detection signal representative of an intensity of the received scattered radiation;
   analyzing the detection signal to determine a position of the metrology mark; and
   determining at least one characteristic of a structure on the substrate based on the analyzing,
   wherein the metrology mark has an enhanced optical response at the plurality of wavelengths.
14. The method of clause 13, wherein the at least one characteristic of the structure includes a thickness of one or more layers of the structure.
15. The method of clause 13, wherein the metrology mark is sub-segmented.
16. The method of clause 15, wherein the metrology mark includes a periodic structure including a substructure having a plurality of elements having width different from one another.
17. The method of clause 16, wherein the substructure includes two elements having different widths.
18. The method of clause 17, wherein the width of the lines of the plurality of elements have decreasing/increasing line widths.
19. The method of clause 13, further comprising
   determining a response of the metrology mark at the plurality of wavelengths based on a predetermined model; and
   comparing the detected intensities to the response to determine the at least one characteristic.
20. A lithography apparatus comprising:
   an illumination apparatus configured to illuminate a pattern of a patterning device;
   a projection system configured to project an image of the pattern onto a substrate; and
   an alignment system including:
      an illumination system configured to generate radiation at a plurality of wavelengths and to irradiate a metrology mark on a substrate,
      a detection system configured to detect light intensities at a plurality of wavelengths based on light scattered from the metrology mark, and
      processing circuitry configured to:
         analyze the detected light intensities to determine a position of the metrology mark, and
         determine at least one characteristic of a structure on the substrate based on the analyzing,
   wherein the metrology mark is configured to enhance an optical response at the plurality of wavelengths.

Commercially available examples of alignment sensors are the previously mentioned SMASH™, ORION™, and ATHENA™ sensor by ASML of Netherlands. Structures and functions of alignment sensors have been discussed in reference to FIG. 4 and in U.S. Pat. No. 6,961,116 and U.S. Pub. Appl. No. 2009/195768, which are all incorporated by reference herein in their entireties.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam,” “light,” “illumination,” and the like as used herein may encompass all types of electromagnetic radiation, for example, ultraviolet (UV) radiation (for example, having a wavelength of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The term “substrate” as used herein describes a material onto which material layers are added. In some embodiments, the substrate itself can be patterned and materials added on top of it may also be patterned, or may remain without patterning.

Although specific reference can be made in this text to the use of the apparatus and/or system according to the present disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. An apparatus comprising:
an illumination system configured to generate radiation at a plurality of wavelengths and to irradiate a metrology mark on a substrate;
a detection system configured to detect light intensities at the plurality of wavelengths based on light scattered from the metrology mark; and
processing circuitry configured to:
analyze the detected light intensities to determine a position of the metrology mark, and
determine at least one characteristic of a structure on the substrate based on the analyzing,
wherein the metrology mark is configured to enhance an optical response at the plurality of wavelengths.

2. The apparatus of claim 1, wherein the at least one characteristic of the structure includes a thickness of one or more layers of the structure.

3. The apparatus of claim 1, wherein the metrology mark is sub-segmented.

4. The apparatus of claim 3, wherein the metrology mark includes a periodic structure including a substructure having a plurality of elements having width different from one another.

5. The apparatus of claim 4, wherein the substructure includes two elements having different widths.

6. The apparatus of claim 4, wherein the plurality of elements has decreasing/increasing line widths.

7. The apparatus of claim 3, wherein the metrology mark includes conjugate pairs.

8. The apparatus of claim 3, wherein the metrology mark includes a periodic structure in a first dimension, the periodic structure including a substructure having a plurality of elements having a periodicity in a second dimension, the first direction being perpendicular to the second direction.

9. The apparatus of claim 1, wherein the analyzing includes determining positioning variations of the metrology mark at the plurality of wavelengths based on the detected light intensities.

10. The apparatus of claim 1, wherein the processing circuitry is further configured to:
determine a response of the metrology mark at the plurality of wavelengths based on a predetermined model; and
compare the detected intensities to the modeled response to determine the at least one characteristic.

11. The apparatus of claim 10, wherein the processing circuitry is further configured to:
acquire data corresponding to the at least one characteristic from an external system;
compare the determined at least one characteristic of the structure with the acquired data; and
update the predetermined model based on the comparison.

12. The apparatus of claim 1, wherein
the illumination system is further configured to generate radiation at different polarizations;
the detection system is further configured to detect light intensities at the different polarizations; and
the analyzing is based on the detected light intensities at the plurality of wavelengths and at the different polarizations.

13. A method comprising:
irradiating a metrology mark on a substrate with radiation at a plurality of wavelengths;
receiving scattered radiation at a detector, the scattered radiation including radiation scattered from the metrology mark;
generating a detection signal representative of an intensity of the received scattered radiation;
analyzing the detection signal to determine a position of the metrology mark; and
determining at least one characteristic of a structure on the substrate based on the analyzing,
wherein the metrology mark has an enhanced optical response at the plurality of wavelengths.

14. The method of claim 13, wherein the at least one characteristic of the structure includes a thickness of one or more layers of the structure.

15. The method of claim 13, wherein the metrology mark is sub-segmented.

16. The method of claim 15, wherein the metrology mark includes a periodic structure including a substructure having a plurality of elements having width different from one another.

17. The method of claim 16, wherein the substructure includes two elements having different widths.

18. The method of claim 17, wherein the width of the lines of the plurality of elements have decreasing/increasing line widths.

19. The method of claim 13, further comprising
determining a response of the metrology mark at the plurality of wavelengths based on a predetermined model; and
comparing the detected intensities to the response to determine the at least one characteristic.

20. A lithography apparatus comprising:
an illumination apparatus configured to illuminate a pattern of a patterning device;
a projection system configured to project an image of the pattern onto a substrate; and
an alignment system including:
an illumination system configured to generate radiation at a plurality of wavelengths and to irradiate a metrology mark on a substrate,
a detection system configured to detect light intensities at a plurality of wavelengths based on light scattered from the metrology mark, and
processing circuitry configured to:
analyze the detected light intensities to determine a position of the metrology mark, and
determine at least one characteristic of a structure on the substrate based on the analyzing,
wherein the metrology mark is configured to enhance an optical response at the plurality of wavelengths.
